(19) United States
(12) Patent Application Publication
(10) Pub. No.: US 2026/0082600 A1
(43) Pub. Date: Mar. 19, 2026

(54) ELECTRONIC DEVICE AND METHOD OF MANUFACTURING ELECTRONIC DEVICE

(71) Applicants: ADVANTEST CORPORATION, Tokyo (JP); INSTITUTE OF SCIENCE TOKYO, Tokyo (JP)

(72) Inventors: Shinji SUGATANI, Saitama (JP); Takayuki OHBA, Kanagawa (JP); Shuji UEHARA, Gunma (JP); Masaki TAKAKUWA, Saitama (JP)

(21) Appl. No.: 19/310,935

(22) Filed: Aug. 27, 2025

(30) Foreign Application Priority Data
Sep. 18, 2024 (JP) 2024-161163

(51) Int. Cl. H10D 1/68; H01L 21/66; H01L 21/768; H01L 23/00; H01L 23/48; H01L 25/16

(52) U.S. Cl. CPC H10D 1/714; H10D 1/716; H10P 74/207; H10W 20/20; H10W 90/00; H10W 20/01; H10W 90/728

(57) ABSTRACT

There is provided an electronic device including: a connection substrate which is provided with a plurality of capacitor structure portions; an electronic element which is provided above the connection substrate; connection wiring which connects the electronic element to the connection substrate, in which the plurality of capacitor structure portions have at least one connection capacitor portion which is connected to the connection wiring, and at least one non-connection capacitor portion which is not connected to the connection wiring. The non-connection capacitor portion may be a capacitor in a short state or an open state. The connection substrate may be a first semiconductor wafer.

The contents of the following patent application(s) are incorporated herein by reference: NO. 2024-161163 filed in JP on Sep. 18, 2024.

### BACKGROUND

### 1. Technical Field

The present invention relates to an electronic device and a method of manufacturing an electronic device.

### 2. Related Art

Patent Document 1 discloses “providing a trench capacitor capable of improving a yield, and a manufacturing method of the trench capacitor” (in the Abstract). Patent Document 2 discloses “providing a capacitor component applicable to the decoupling capacitor corresponding to a semiconductor element of higher frequency” (in the Abstract). Patent Document 3 discloses a “method for securely detecting defective mounting of a capacitor with a small inspection man-hour using ordinary inspection equipment” (in the Abstract). Patent Document 4 discloses “surely inspecting whether or not a connection failure and the like are caused in a capacitor built in a substrate” (in the Abstract). Patent Document 5 discloses “providing an interposer capacitor in which an electric capacity can be increased sufficiently while preventing a short circuit in a capacitor structure sufficiently” (in the Abstract).

### RELATED ART DOCUMENTS

### Patent Document

Patent Document 1: Japanese Patent Application Publication No. 2020-136455
Patent Document 2: Japanese Patent Application Publication No. 2006-185935
Patent Document 3: Japanese Patent Application Publication No. 2014-187127
Patent Document 4: Japanese Patent Application Publication No. 2014-112081
Patent Document 5: Japanese Patent Application Publication No. 2007-141886

### BRIEF DESCRIPTION OF THE DRAWINGS

FIG. 1 is a diagram showing an example of an electronic device 100 according to one embodiment of the present invention.

FIG. 2 is a diagram showing another example of the electronic device 100 according to one embodiment of the present invention.

FIG. 3A is an enlarged view of an example of one capacitor structure portion 12 in FIG. 2.

FIG. 3B is an enlarged view of another example of one capacitor structure portion 12 in

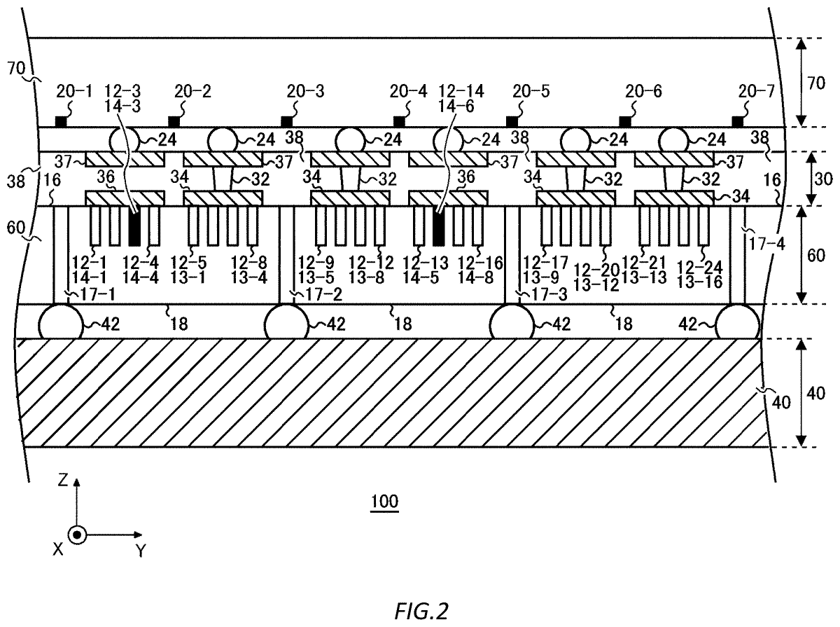

FIG. 2.

FIG. 4 is a diagram showing an example in a top view of a first semiconductor wafer 60.

FIG. 5 shows an enlarged view of one region 62 in FIG. 4.

FIG. 6 is a diagram showing an example of a cross section A-A′ in FIG. 5.

FIG. 7 is a diagram showing another example of the electronic device 100 according to one embodiment of the present invention.

FIG. 8 is a block diagram showing an example of an electronic device design system 200 according to one embodiment of the present invention.

FIG. 9 is a diagram showing an example of a method of manufacturing the electronic device according to one embodiment of the present invention.

FIG. 10 is a diagram showing an example of a method of manufacturing the electronic device according to one embodiment of the present invention.

FIG. 11 is a diagram showing an example of a method of manufacturing the electronic device according to one embodiment of the present invention.

FIG. 12 is a diagram showing an example of a method of manufacturing the electronic device according to one embodiment of the present invention.

FIG. 13 is a diagram showing an example of a method of manufacturing the electronic device according to one embodiment of the present invention.

FIG. 14 is a diagram showing another example of the method of manufacturing the electronic device according to one embodiment of the present invention.

FIG. 15 is a block diagram showing another example of the electronic device design system 200 according to one embodiment of the present invention.

FIG. 16 is a diagram showing another example of the method of manufacturing the electronic device according to one embodiment of the present invention.

FIG. 17 is a diagram showing another example of the method of manufacturing the electronic device according to one embodiment of the present invention.

FIG. 18 is a schematic diagram of a part of an upper surface of a liquid crystal layer 290, in a state in which a voltage is applied between the upper surface of the liquid crystal layer 290 and a connection substrate 10.

### DESCRIPTION OF EXEMPLARY EMBODIMENTS

Hereinafter, embodiments of the present invention will be described. However, the following embodiments are not for limiting the invention according to the claims. In addition, not all combinations of features described in the embodiments are essential to a solution of the invention.

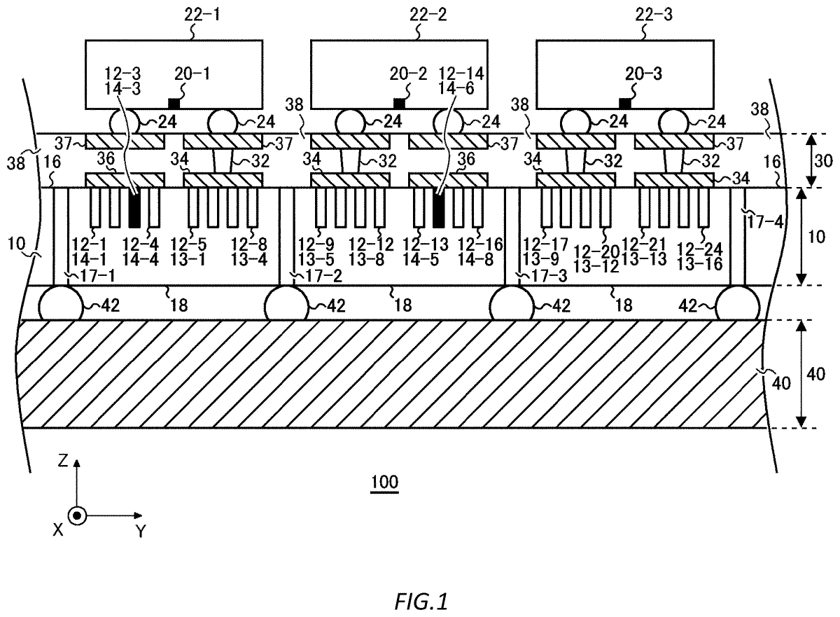

FIG. 1 is a diagram showing an example of an electronic device 100 according to one embodiment of the present invention. The electronic device 100 in the present example is a semiconductor package in which a connection substrate 10 is mounted above a circuit board 40, and a semiconductor chip 22 is mounted above the connection substrate 10. The electronic device 100 includes the connection substrate 10, an electronic element 20, and connection wiring 32. In the present example, the semiconductor chip 22 has the electronic element 20.

The connection substrate 10 is a substrate which electrically connects the circuit board 40 to the semiconductor chip 22. The connection substrate 10 is, for example, an interposer provided between the circuit board 40 and the semiconductor chip 22. The connection substrate 10 may be a first semiconductor wafer 60 (described below). When the connection substrate 10 is the first semiconductor wafer 60 (described below), the electronic device 100 in FIG. 1 has a form of a so-called CoWoS (Chip on Wafer on Substrate, registered trademark).

The electronic device 100 may include the circuit board 40. The circuit board 40 is, for example, a PCB (Printed Circuit Board).

In the present specification, the electronic element 20 refers to an active element which is operated based on supplied power. The active element includes, for example, a transistor, a diode, and the like. In the present specification, an electrical element 120 (described below) refers to the active element described above and a passive element which accumulates or consumes the supplied power. The passive element is, for example, a capacitor, a resistor, a coil, or the like. A capacitor structure portion 12 is an example of the electrical element 120.

The connection substrate 10 is provided with a plurality of capacitor structure portions 12. The capacitor structure portion 12 is a structure portion designed as a capacitor, in the connection substrate 10. The structure portion includes at least either a member such as a conductor additionally provided at the connection substrate 10 having an insulating property, or a part of a groove, unevenness, and the like formed in the connection substrate 10. The capacitor structure portion 12 in the present example is a trench structure provided from an upper surface 16 of the connection substrate 10 to an inside.

A ratio of a depth in a Z axis direction to a width in a Y axis direction of the trench structure (a so-called aspect ratio) may be 2.5 or more and 30 or less, or may be 10 or more and 20 or less. The width in the Y axis direction is, for example, 2 μm or more and 4 μm or less. The depth in the Z axis direction is, for example, 10 μm or more and 60 μm or less. A ratio of a width in an X axis direction to the width in the Y axis direction of the trench structure may be 0.5 or more and 1.5 or less, may be 0.6 or more and 1.4 or less, or may be 0.8 or more and 1.2 or less.

The upper surface 16 is a surface of two surfaces of the connection substrate 10, which faces the electronic element 20. A lower surface 18 is a surface of the two surfaces of the connection substrate 10, which faces the circuit board 40. FIG. 1 shows 24 capacitor structure portions 12 (a capacitor structure portion 12-1 to a capacitor structure portion 12-24).

The plurality of capacitor structure portions 12 have at least one connection capacitor portion 13 and at least one non-connection capacitor portion 14. The connection capacitor portion 13 is connected to the connection wiring 32. The non-connection capacitor portion 14 is not connected to the connection wiring 32. FIG. 1 shows 16 connection capacitor portions 13 (a connection capacitor portion 13-1 to a connection capacitor portion 13-16) and 8 non-connection capacitor portions 14 (a non-connection capacitor portion 14-1 to a non-connection capacitor portion 14-8).

In FIG. 1, the connection capacitor portion 13-1 refers to the capacitor structure portion 12-5 which functions as a connection capacitor. That is, the connection capacitor portion 13-1 is the same structure portion as the capacitor structure portion 12-5. Similarly, the connection capacitor portion 13-2 to the connection capacitor portion 13-16 refer to the capacitor structure portion 12-6 to the capacitor structure portion 12-12, and the capacitor structure portion 12-17 to the capacitor structure portion 12-24. In FIG. 1, the non-connection capacitor portion 14-1 refers to the capacitor structure portion 12-1 which functions as a non-connection capacitor. That is, the non-connection capacitor portion 14-1 is the same structure portion as the capacitor structure portion 12-1. Similarly, the non-connection capacitor portion 14-2 to the non-connection capacitor portion 14-8 refer to the capacitor structure portion 12-2 to the capacitor structure portion 12-4, and the capacitor structure portion 12-13 to the capacitor structure portion 12-16.

The connection capacitor portion 13 is the capacitor structure portion 12 which functions as a capacitor as designed. That is, the connection capacitor portion 13 is a good capacitor. The plurality of non-connection capacitor portions 14 include the capacitor structure portion 12 for which it is difficult to function as a capacitor even though it is designed as a capacitor. That is, at least one non-connection capacitor portion 14 is a defective capacitor. In the example of FIG. 1, the capacitor structure portion 12-3 and the capacitor structure portion 12-14 which are black and rectangular, are defective capacitors, respectively. The defective capacitors are the non-connection capacitor portion 14-3 and the non-connection capacitor portion 14-6. The plurality of non-connection capacitor portions 14 may include good capacitors. In the example of FIG. 1, the capacitor structure portion 12-1, the capacitor structure portion 12-2, the capacitor structure portion 12-4, the capacitor structure portion 12-13, the capacitor structure portion 12-15, and the capacitor structure portion 12-16 which are white and rectangular, are the good capacitors, respectively. The good capacitors are the non-connection capacitor portion 14-1, the non-connection capacitor portion 14-2, the non-connection capacitor portion 14-4, the non-connection capacitor portion 14-5, the non-connection capacitor portion 14-7, and the non-connection capacitor portion 14-8.

When the plurality of capacitor structure portions 12 are formed at the connection substrate 10, a yield of the plurality of capacitor structure portions 12 may be less than 100%. The yield of the plurality of capacitor structure portions 12 refers to a ratio of the number of good capacitors (the capacitor structure portions 12 which are white and rectangular in FIG. 1) to the total number of the plurality of capacitor structure portions 12.

At least one non-connection capacitor portion 14 may be a capacitor in a shorted state or an open state. The at least one non-connection capacitor portion 14 is the defective capacitor (the capacitor structure portion 12 which is black and rectangular in FIG. 1). The shorted state refers to a state in which two electrodes of the capacitor are shorted, thereby causing a leakage current to flow between the two electrodes. A capacitor with a current flowing between the two electrodes that is higher than or equal to a predetermined threshold value, may be considered to be a capacitor in the shorted state. The open state refers to a state in which at least one of two lines of the wiring which are respectively connected to the two electrodes is broken, thereby causing a resistance value to be infinite between the two electrodes. A capacitor with an electrical resistance value that is higher than or equal to a predetermined resistance threshold value between the two electrodes, may be set as a capacitor in the open state. The capacitor structure portion 12 with a capacitance value outside an allowable range may be set as being defective. The allowable range may be set in advance by a user, manufacturer, or the like.

The plurality of capacitor structure portions 12 may correspond to one electronic element 20. The expression that the capacitor structure portion 12 corresponds to the electronic element 20, means that the electronic element 20 and the capacitor structure portion 12 are in a connection relationship on a circuit. In the present example, eight capacitor structure portions 12 correspond to one electronic element 20. In the present example, the capacitor structure portion 12-1 to the capacitor structure portion 12-8 correspond to an electronic element 20-1; the capacitor structure portion 12-9 to the capacitor structure portion 12-16 correspond to an electronic element 20-2; and the capacitor structure portion 12-17 to the capacitor structure portion 12-24 correspond to an electronic element 20-3.

In the present specification, technical matters may be described by using orthogonal coordinate axes of an X axis, a Y axis, and a Z axis. In the present specification, a plane parallel to a substrate surface of the connection substrate 10 and a board surface of the circuit board 40 is defined as an XY plane, and a direction from the circuit board 40 to the semiconductor chip 22 is defined as the Z axis direction. In the present specification, a direction from the capacitor structure portion 12-1 to the capacitor structure portion 12-24 in the XY plane is set as the Y axis direction, and a direction orthogonal to the Y axis in the XY plane is set as the X axis direction. The Z axis direction may be a direction parallel to a vertical direction, and the XY plane may be a horizontal plane.

In the present specification, a semiconductor chip 22 side in the electronic device 100 is referred to as an “upper” side and a circuit board 40 side is referred to as a “lower” side. In the present specification, a view in a direction from the semiconductor chip 22 to the circuit board 40 is referred to as a top view.

The connection substrate 10 may be provided with a plurality of through via structure portions 17. A through via structure portion 17 is a structure portion designed as a through via, in the connection substrate 10. The through via structure portion 17 may be formed by filling an opening portion of a trench shape formed from the upper surface 16 to the lower surface 18, with metal such as Cu (copper).

The through via structure portion 17 may be provided alongside the capacitor structure portion 12 in the Y axis direction. Two adjacent through via structure portions 17 in the Y axis direction (for example, a through via structure portion 17-1 and a through via structure portion 17-2) may be arranged to be spaced apart at a predetermined distance in the Y axis direction. The plurality of capacitor structure portions 12 may be provided between two adjacent through via structure portions 17 in the Y axis direction. In the present example, the capacitor structure portion 12-1 to the capacitor structure portion 12-8 are provided between the through via structure portion 17-1 and the through via structure portion 17-2; the capacitor structure portion 12-9 to the capacitor structure portion 12-16 are provided between the through via structure portion 17-2 and a through via structure portion 17-3; and the capacitor structure portion 12-17 to the capacitor structure portion 12-24 are provided between the through via structure portion 17-3 and a through via structure portion 17-4.

The electronic element 20 is provided above the connection substrate 10. The electronic element 20 is, for example, a transistor, diode, or the like. The connection wiring 32 electrically connects the electronic element 20 to the connection substrate 10. The electronic device 100 may include a first bump 24.

The electronic device 100 may further include a wiring layer 30. In the present example, the wiring layer 30 is provided in contact with the upper surface 16 of the connection substrate 10. The wiring layer 30 may be formed of a photosensitive material 38.

The connection substrate 10 may have at least one first connection electrode 34 and at least one second connection electrode 36. The first connection electrode 34, the second connection electrode 36, and the connection wiring 32 may be provided inside the wiring layer 30. The first connection electrode 34 is connected to the connection capacitor portion 13. The first connection electrode 34 may be provided to cover an upper part of the connection capacitor portion 13. One first connection electrode 34 may be provided to cover the upper part of one connection capacitor portion 13. The second connection electrode 36 is connected to the non-connection capacitor portion 14. The second connection electrode 36 may be provided to cover an upper part of non-connection capacitor portion 14. One second connection electrode 36 may be provided to cover the upper part of one non-connection capacitor portion 14. The first connection electrode 34 is connected to the connection wiring 32. The second connection electrode 36 is not connected to the connection wiring 32.

The connection substrate 10 may further include at least one upper electrode 37. The upper electrode 37 may be provided inside the wiring layer 30. An upper surface of the upper electrode 37 may be exposed to an upper surface of the wiring layer 30. In the Z axis direction, one upper electrode 37 may be provided above one first connection electrode 34 or one second connection electrode 36. The first connection electrode 34 and the upper electrode 37 are connected by the connection wiring 32. The second connection electrode 36 is not connected to the upper electrode 37 by the connection wiring 32. The connection wiring 32 may be arranged at a position overlapping the first connection electrode 34 and the upper electrode 37 in the top view.

Above the upper electrode 37, the first bump 24 may be provided in contact. In the present example, the power supplied from the connection substrate 10 is supplied to the electronic element 20 via the first connection electrode 34, the connection wiring 32, the upper electrode 37, and the first bump 24.

These days, semiconductor devices such as the electronic device 100 are in a trend to reduce an operating voltage of the electronic element 20 to decrease power consumption and their high-speed operation. In addition, due to an increase of a size of the circuit mounted on the electronic device 100, scaling the electronic elements 20 up in the number tends to expand layout area. As a result, there is a tendency for total power consumed by the plurality of electronic elements 20 to be increased. In addition, due to an increase of a size of the circuit mounted on the electronic device 100, an increase in the active current in a power rail network tends to increase the total power consumption. As a result, there is a tendency for the power consumption of the electronic device 100 to be increased. By these trends, in the electronic device 100, a voltage drop on the power supply wiring can become a problem. By suppressing this voltage drop by using the capacitor, it is possible to ensure a quality of the power supply voltage.

When the voltage drop on the power supply wiring is suppressed by using the capacitor, it is preferable for a decoupling capacitance to be enhanced. However, when the capacitance is increased, area of the capacitor is simply increased. Therefore, it is preferable to increase the capacitance of the capacitor while the capacitance per unit area of the connection substrate 10 is ensured.

In the electronic device 100, the connection wiring 32 is arranged based on a state of the capacitor structure portion 12. The state of the capacitor structure portion 12 may refer to either goodness or defectiveness of the capacitor structure portion 12, or the capacitance value. In the present example, the connection wiring 32 is connected to the good capacitor structure portion 12, but is not connected to the defective capacitor structure portion 12. That is, the connection wiring 32 is connected to the good capacitor structure portion 12 while avoiding the defective capacitor structure portion 12. Therefore, it becomes easy to ensure the capacitance per unit area of the connection substrate 10. In addition, by manufacturing the surplus capacitor structure portion 12 for the connection substrate 10 in advance, the entirety of the connection substrate 10 or the electronic device 100 is prevented from becoming defective, even when some capacitor structure portions 12 become defective, by forming the wiring afterward such that the remaining capacitor structure portion 12 is used.

The first connection electrode 34 and the second connection electrode 36 may be provided in the upper surface 16 of the connection substrate 10. Two or more capacitor structure portions 12 may be connected to the first connection electrode 34. Two or more connection capacitor portions 13 may be connected to the first connection electrode 34. To the first connection electrode 34, the good capacitor may be connected, and the defective capacitor may not be connected. Two or more capacitor structure portions 12 may be connected to the second connection electrode 36. One or more non-connection capacitor portions 14 may be connected to the second connection electrode 36. At least one defective capacitor may be connected to the second connection electrode 36. The good capacitor may not be connected to, or may be connected to the second connection electrode 36.

In the present example, the plurality of capacitor structure portions 12 are connected to the same first connection electrode 34. For each first connection electrode 34, it is determined whether to provide the connection wiring 32, or not to provide the connection wiring 32. The first connection electrode 34 corresponding to the defective capacitor (for example, the capacitor structure portion 12-3) is not provided with the connection wiring 32. Therefore, in addition to the defective capacitor (for example, the capacitor structure portion 12-3), the good capacitor corresponding to the same first connection electrode 34 as that for the defective capacitor (for example, the capacitor structure portions 12-1, 12-2, 12-4) also serves as the non-connection capacitor portion 14. On the other hand, when all of the plurality of capacitors connected to the common first connection electrode 34 are good, these capacitors serve as the connection capacitor portion 13.

The circuit board 40 is provided below the connection substrate 10. The circuit board 40 may have a second bump 42. The second bump 42 may be provided in an upper surface of the circuit board. In the present example, the second bump 42 is electrically connected to the through via structure portion 17 of the connection substrate 10. The second bump 42 may be connected to the through via structure portion 17 at the lower surface 18 of the connection substrate 10.

FIG. 2 is a diagram showing another example of the electronic device 100 according to one embodiment of the present invention. In the electronic device 100 in the present example, the connection substrate 10 is the first semiconductor wafer 60. The electronic device 100 in the present example includes a second semiconductor wafer 70 instead of the semiconductor chip 22 shown in FIG. 1. In the present example, one or more electronic elements 20 are provided at the second semiconductor wafer 70. The electronic device 100 in the present example is different from the electronic device 100 in FIG. 1 in these respects. The electronic device 100 in FIG. 2 has a form of a so-called WoW (Wafer on Wafer).

The first semiconductor wafer 60 and the second semiconductor wafer 70 may be substrates which are cut out from an ingot and are not yet singulated. The first semiconductor wafer 60 and the second semiconductor wafer 70 may be substrates of a disc shape in which an orientation flat or a notch that indicates a crystal orientation of the semiconductor, is formed.

The first semiconductor wafer 60 and the second semiconductor wafer 70 may be Si (silicon) wafers. The first semiconductor wafer 60 and the second semiconductor wafer 70 may be wafers containing multi-element epitaxial materials (e.g., InGaAs or AlGaN) which are based on GaAs (gallium arsenide), GaN (gallium nitride), or InP (indium phosphide). A semiconductor material of the first semiconductor wafer 60 may be the same as, or may be different from a semiconductor material of the second semiconductor wafer 70.

When the first semiconductor wafer 60 is a Si (silicon) wafer, the through via structure portion 17 is, for example, a TSV (Through Silicon Via). The through via structure portion 17 is provided to pass through from the upper surface 16 to the lower surface 18.

In the present example, the second semiconductor wafer 70 in which the electronic element 20 is formed, is mounted on the first semiconductor wafer 60 in which the capacitor structure portion 12 is formed. As will be described below, a position in a wafer in-plane direction of the second semiconductor wafer 70 is aligned with a position in a wafer in-plane direction of the first semiconductor wafer 60, and the second semiconductor wafer 70 is mounted on the first semiconductor wafer 60. Therefore, it is preferable that a wafer size of the first semiconductor wafer 60 is the same as a wafer size of the second semiconductor wafer 70.

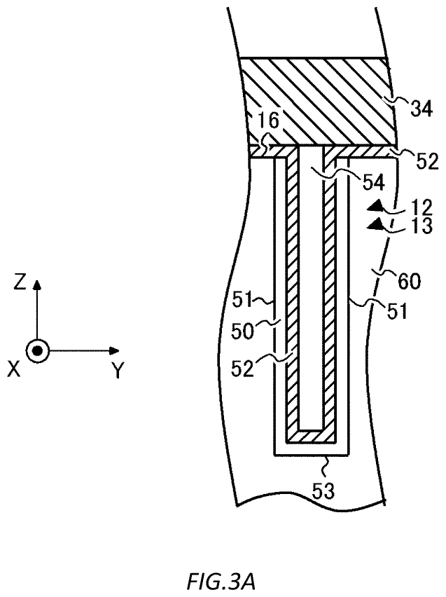

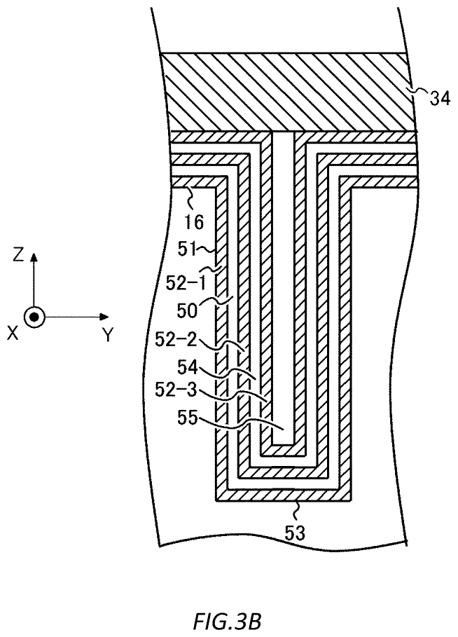

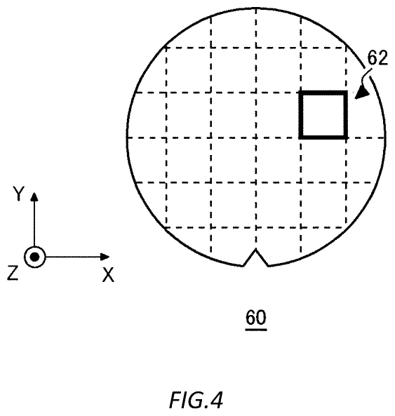

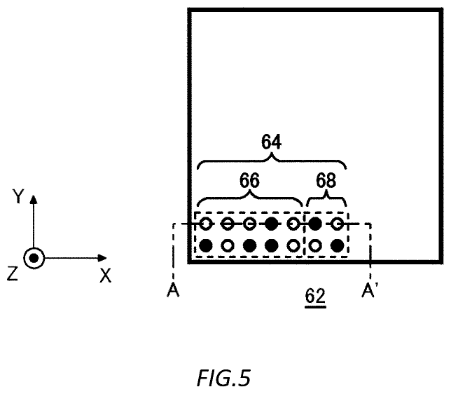

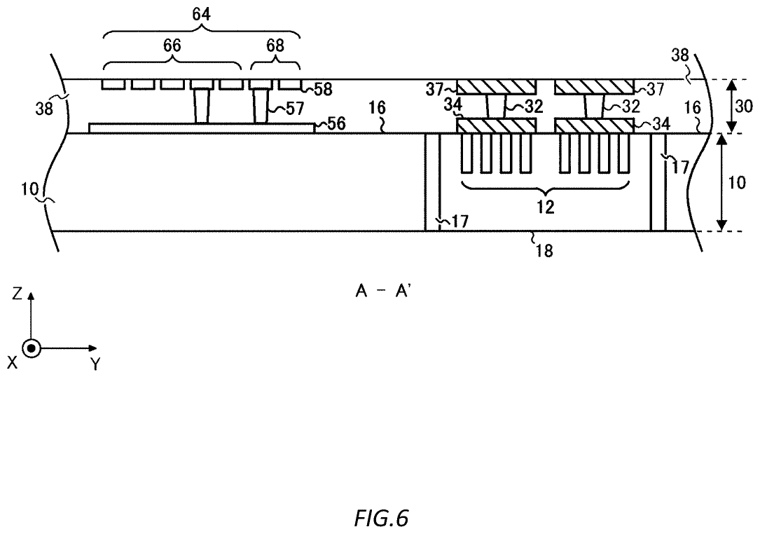

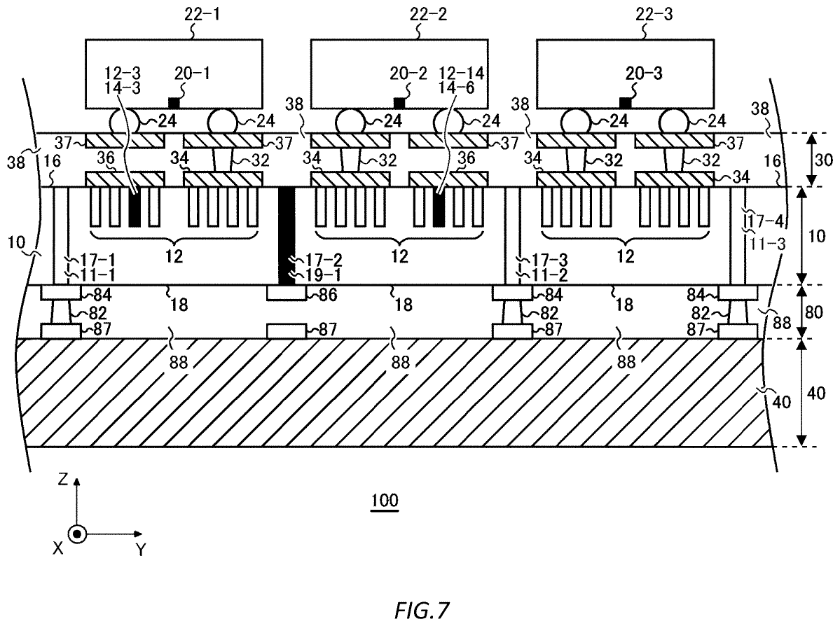

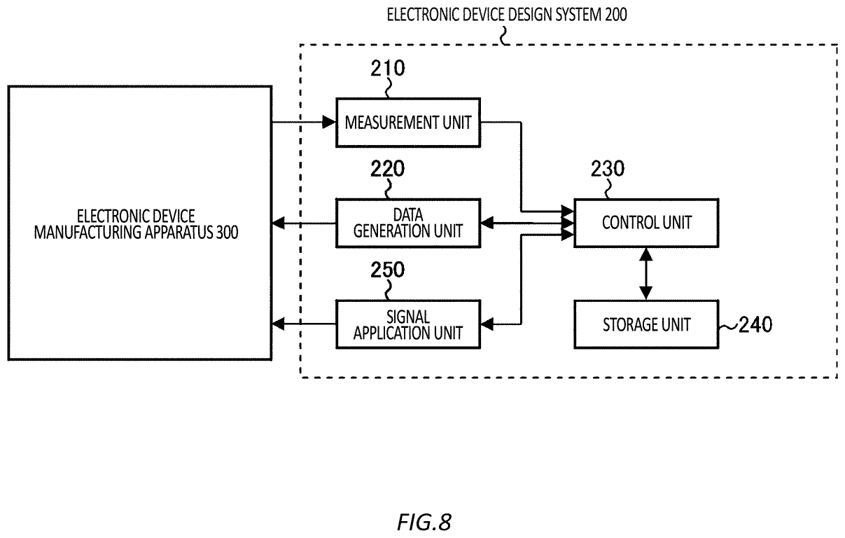

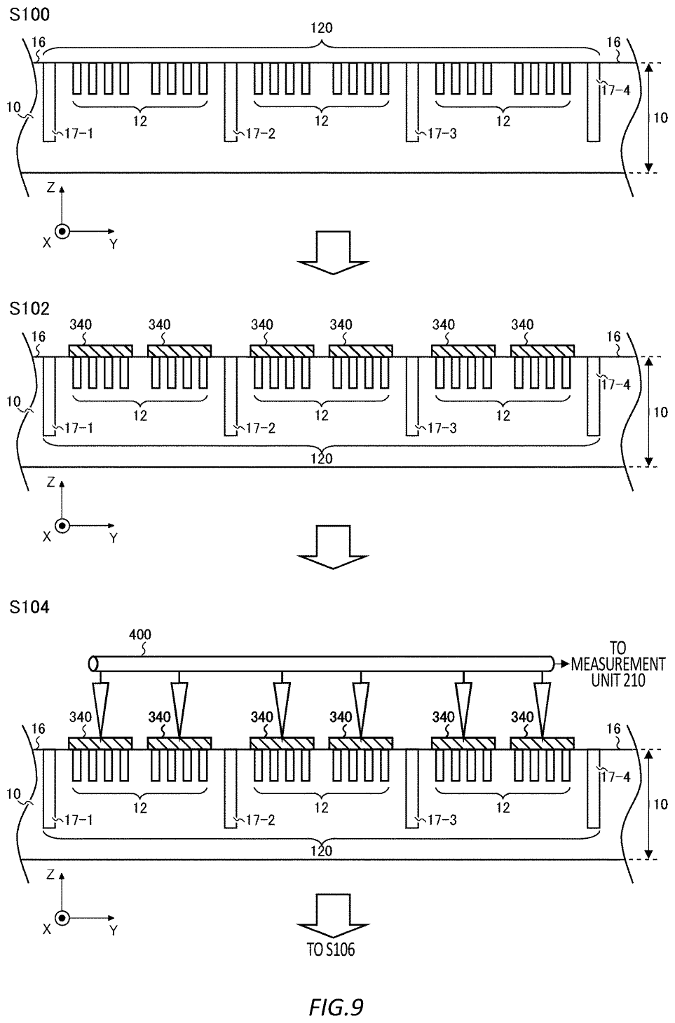

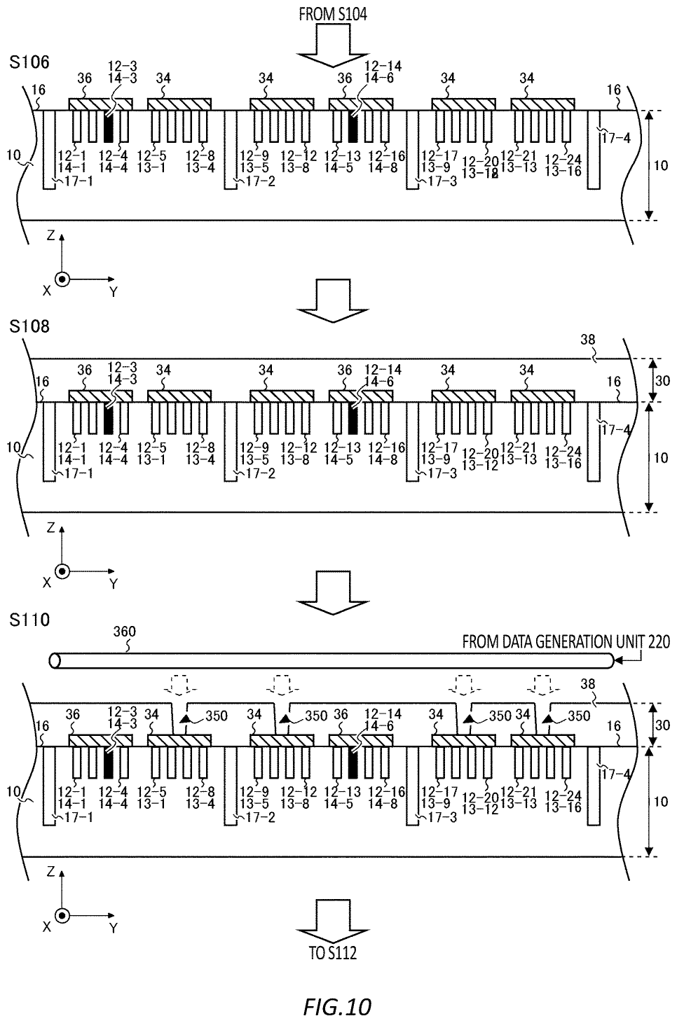

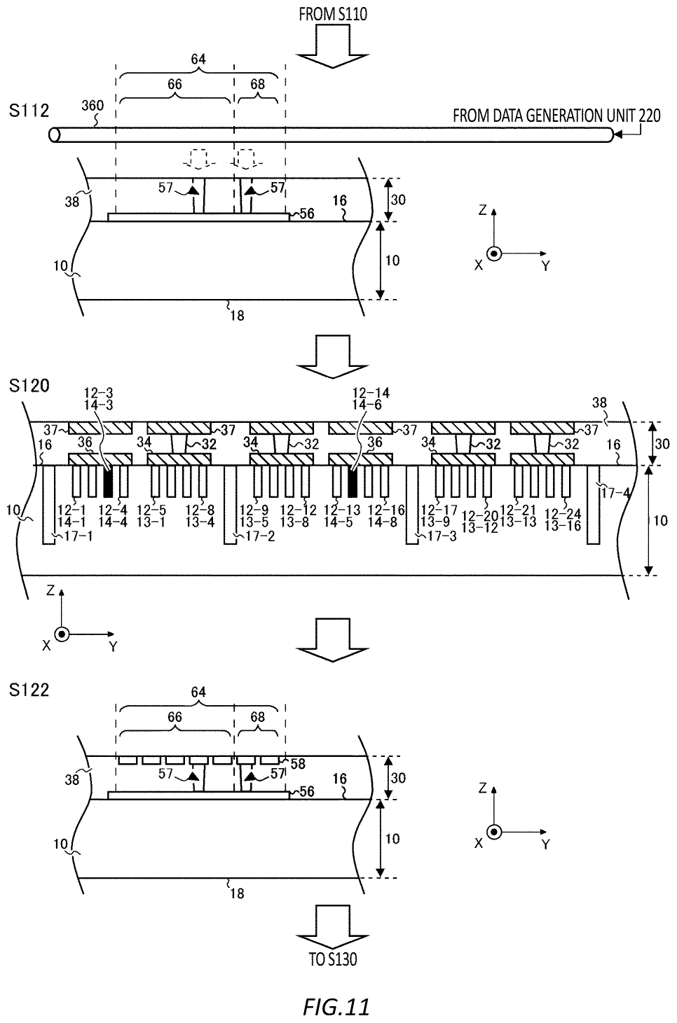

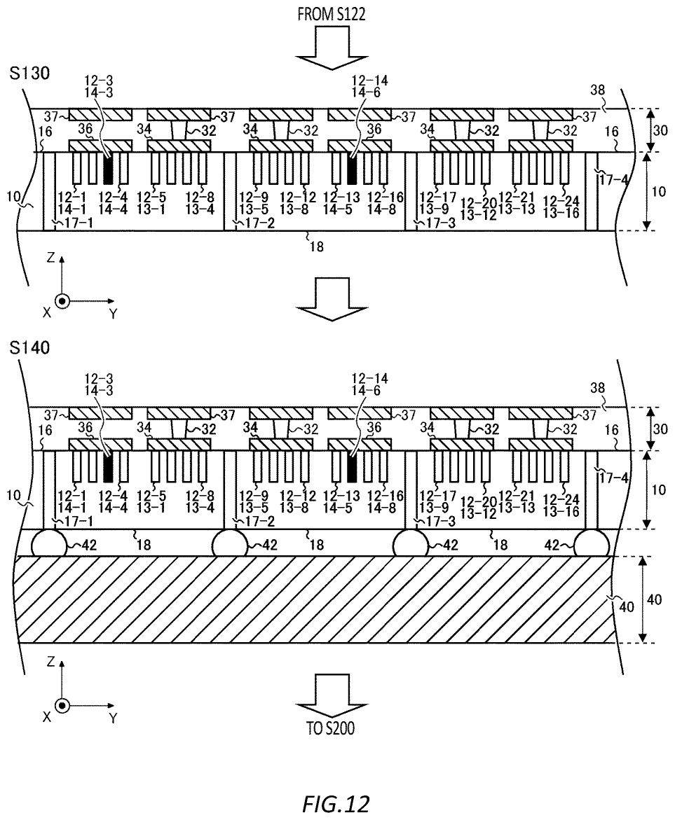

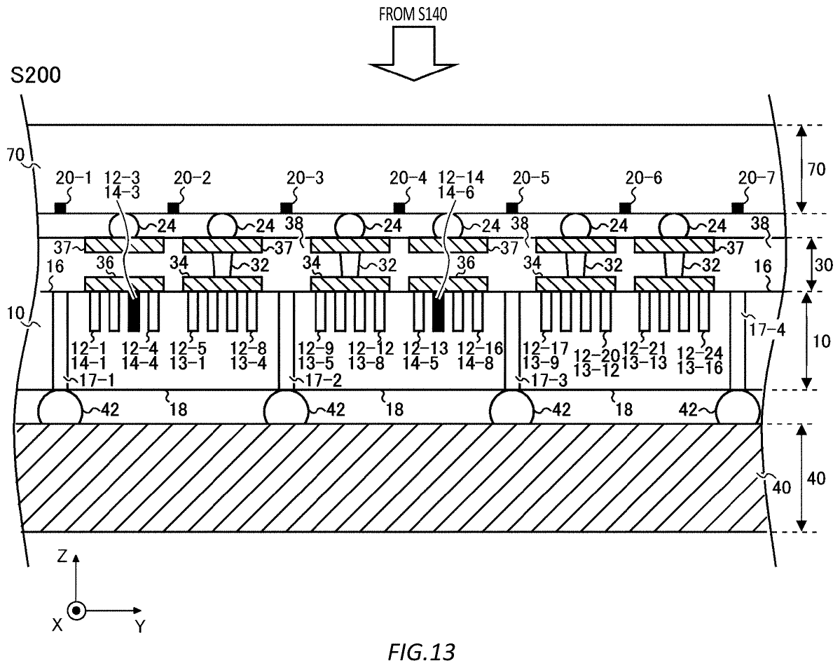

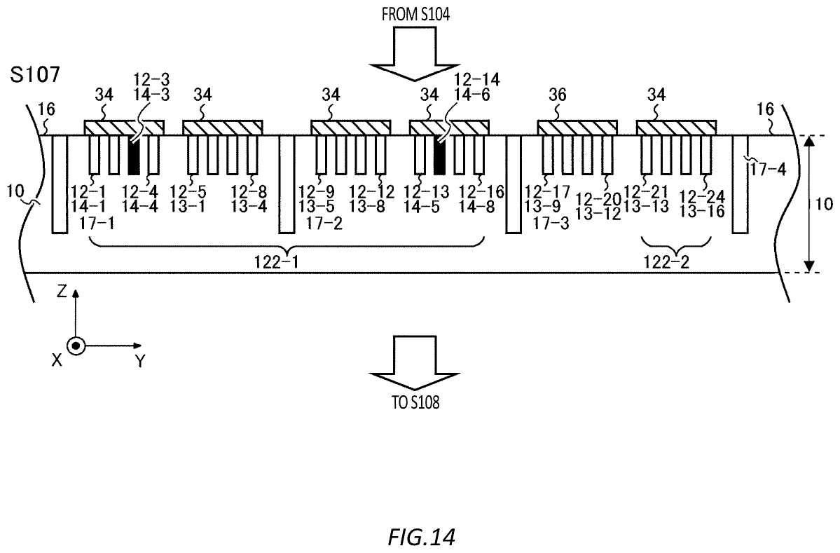

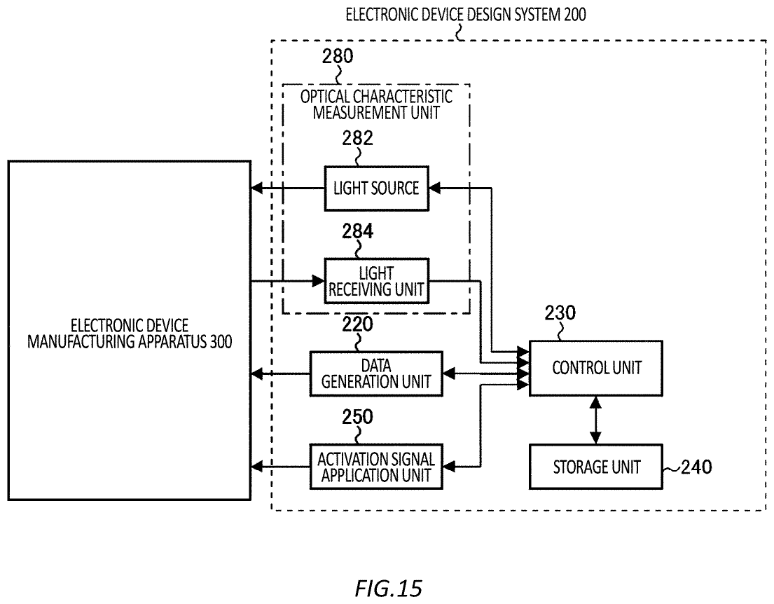

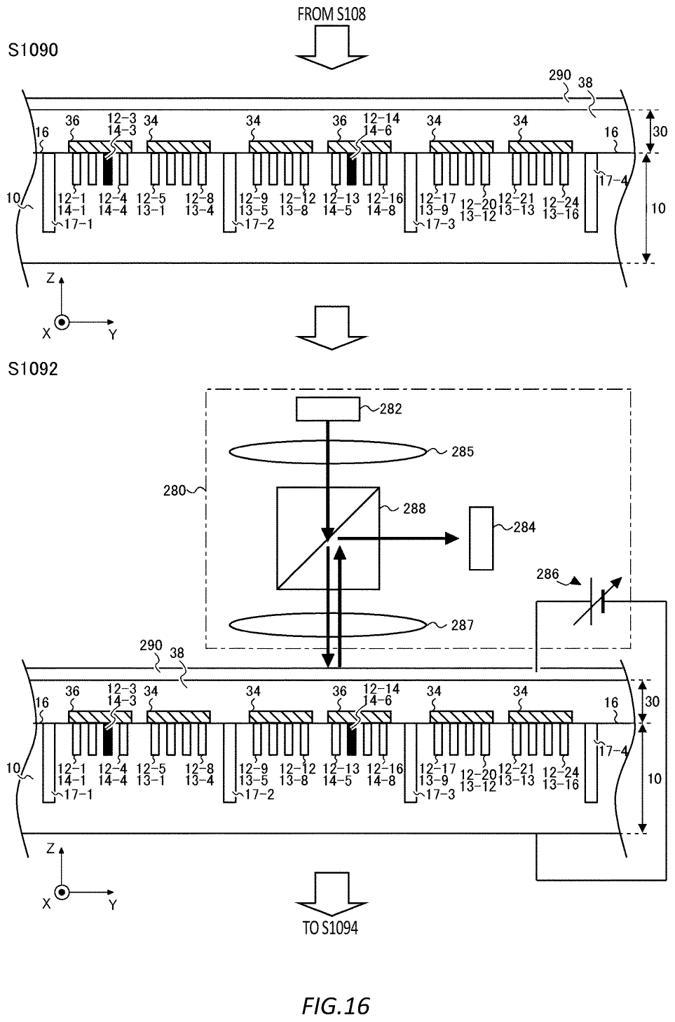

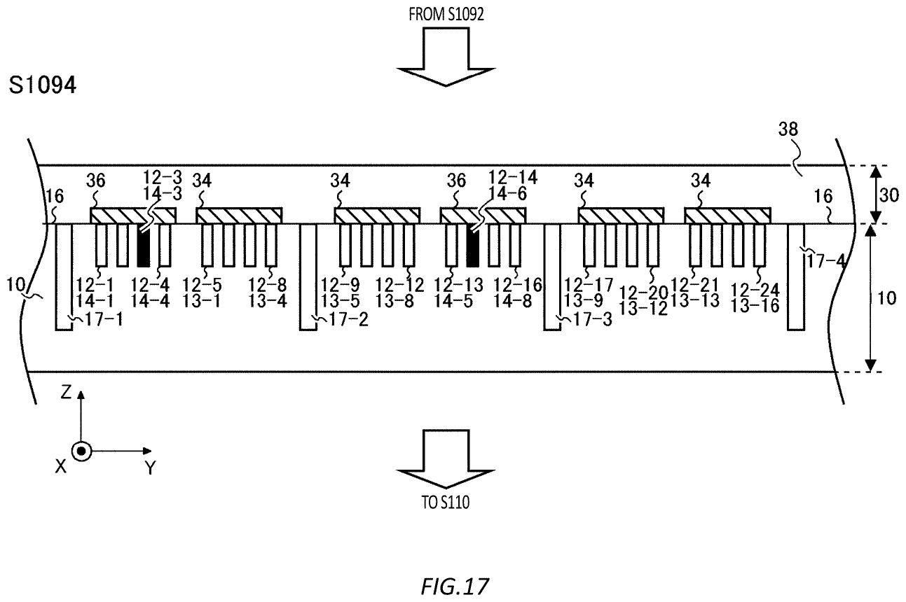

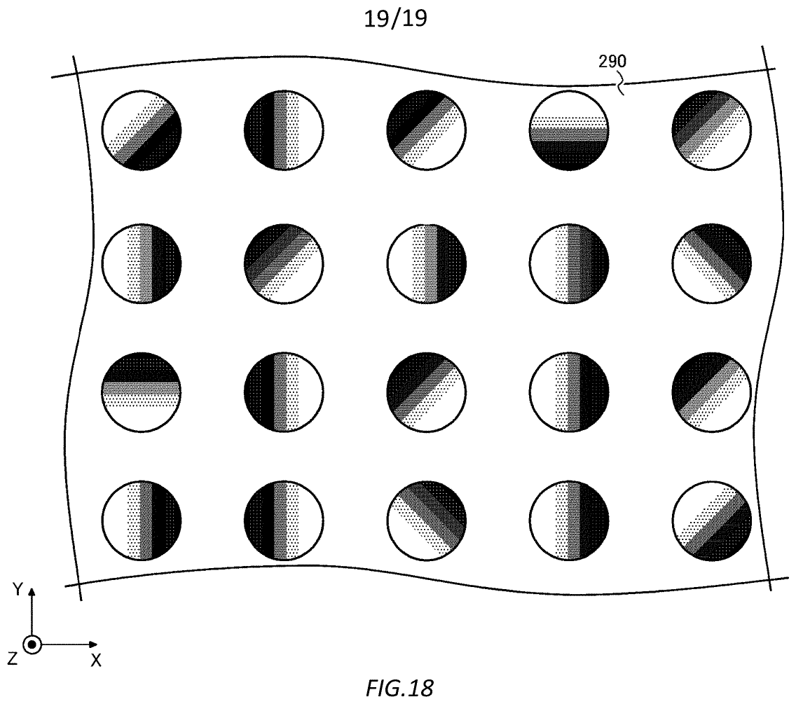

FIG. 3A is an enlarged view of an example of one capacitor structure portion 12 in FIG. 2. FIG. 3A is an example of a case where the capacitor structure portion 12 is the connection capacitor portion 13. The capacitor structure portion 12 in FIG. 3A is a simplified example compared to the capacitor structure portion 12 in FIG. 3B which will be described below. The capacitor structure portion 12 may be a trench structure provided from the upper surface 16 of the first semiconductor wafer 60 to the inside. The trench structure provided from the upper surface 16 to the inside refers to a recess provided in the direction, with the upper surface 16 being a starting point, from the upper surface 16 to the lower surface 18, the recess not passing through from the upper surface 16 to the lower surface 18. A capacitor with a trench structure as in the present example may be referred to as an eDTC (embedded Deep Trench Capacitor). The capacitor structure portion 12 is a structure portion for which it is difficult to individually determine whether each of the plurality of capacitor structure portions 12 is good or defective.

The connection capacitor portion 13 includes a first capacitor electrode 50, a dielectric 52, and a second capacitor electrode 54. In the present example, the first capacitor electrode 50 is provided on an inner wall 51 of the trench structure provided at the first semiconductor wafer 60. The first capacitor electrode 50 may be further provided at a bottom portion 53 of the trench structure. The first capacitor electrode 50 may be continuously provided from the inner wall 51 to the bottom portion 53. A position of an upper end of the first capacitor electrode 50 in the Z axis direction may be the same as a position of the upper surface 16 in the Z axis direction.

The dielectric 52 may be provided in contact with the first capacitor electrode 50, inside the first capacitor electrode 50 in the trench structure. The dielectric 52 may be further provided in the upper surface 16 of the connection substrate 10. The dielectric 52 may be continuously provided from the inside of the first capacitor electrode 50 to the upper surface 16.

The second capacitor electrode 54 may be provided in contact with the dielectric 52, inside the dielectric 52 in the trench structure. A position of an upper end of the second capacitor electrode 54 in the Z axis direction may be the same as a position of an upper end of the dielectric 52 in the Z axis direction.

The first connection electrode 34 may be provided above the connection substrate 10 via the dielectric 52. The first connection electrode 34 may be provided in contact with an upper surface of the dielectric 52 provided in the upper surface 16. In the present example, the first connection electrode 34 is electrically connected to the second capacitor electrode 54, and is not electrically connected to the first capacitor electrode 50.

The first capacitor electrode 50 may be in contact with the first semiconductor wafer 60. By the first capacitor electrode 50 being in contact with the first semiconductor wafer 60, the first capacitor electrode 50 is electrically connected to the first semiconductor wafer 60 without the wiring or the like being interposed. This makes it possible to enhance an area density of the capacitor structure portion 12. The area density of the capacitor structure portion 12 may refer to the capacitance per unit area of the upper surface 16 of the first semiconductor wafer 60, in the top view of the first semiconductor wafer 60, or may refer to the number of the capacitor structure portions 12 per unit area.

FIG. 3B is an enlarged view of another example of one capacitor structure portion 12 in FIG. 2. FIG. 3B is an example of a case where the capacitor structure portion 12 is the connection capacitor portion 13, similar to FIG. 3A. In the present example, the connection capacitor portion 13 further includes a third capacitor electrode 55.

In the present example, a dielectric 52-1 is provided on the inner wall 51, the bottom portion 53, and the upper surface 16. The first capacitor electrode 50 may be provided in contact with the dielectric 52-1, inside the dielectric 52-1 in the trench structure. A dielectric 52-2 may be provided in contact with the first capacitor electrode 50, inside the first capacitor electrode 50 in the trench structure. The second capacitor electrode 54 may be provided in contact with the dielectric 52-2, inside the dielectric 52-2 in the trench structure. A dielectric 52-3 may be provided in contact with the second capacitor electrode 54, inside the second capacitor electrode 54 in the trench structure. The third capacitor electrode 55 may be provided in contact with the dielectric 52-3, inside the dielectric 52-3 in the trench structure.

In the present example, the first connection electrode 34 is provided in contact with an upper surface of the dielectric 52-3. In the present example, the dielectric 52-1 is in contact with the first capacitor electrode 50. In the present example, the first connection electrode 34 is electrically connected to the third capacitor electrode 55.

FIG. 4 is a diagram showing an example in a top view of the first semiconductor wafer 60. The first semiconductor wafer 60 has a plurality of regions 62 in a wafer surface. One region 62 is provided with the capacitor structure portion 12 (refer to FIG. 2) and the through via structure portion 17 (refer to FIG. 2). The one region 62 is arranged in a translationally symmetric manner in the X axis direction and the Y axis direction in the wafer surface.

FIG. 5 shows an enlarged view of one region 62 in FIG. 4. The first semiconductor wafer 60 may be provided with an information portion 64. The information portion 64 includes region information 66 and capacitor information 68. The region information 66 is information indicating the region 62 in the first semiconductor wafer 60. The region information 66 may be information indicating a position of the region 62 in the wafer surface in the first semiconductor wafer 60. The capacitor information 68 is information indicating a capacitor characteristic of at least one capacitor structure portion 12 in the region 62. The capacitor information 68 may be information indicating whether the capacitor structure portion 12 is the connection capacitor portion 13 (that is, the good capacitor structure portion 12), or the non-connection capacitor portion 14 (that is, the defective capacitor structure portion 12); or may be information indicating the capacitance value of the capacitor structure portion 12.

By including the region information 66 and the capacitor information 68 in one region 62, it becomes easy for an electronic device design system 200 (described below) to recognize the capacitor information at a specific position in the wafer surface of the first semiconductor wafer 60. By including the region information 66 and the capacitor information 68 in one region 62, a designer of the electronic device 100 easily recognizes, even after the singulation of the first semiconductor wafer 60 for each region 62, positions where the singulated semiconductor chips were arranged in the wafer surface in the first semiconductor wafer 60, and the capacitor information in the singulated semiconductor chips.

FIG. 6 is a diagram showing an example of a cross section A-A′ in FIG. 5. In FIG. 6, the semiconductor chip 22, the first bump 24, the second bump 42, and the circuit board 40 in FIG. 2 are omitted. The information portion 64 may have a first dummy electrode 56, a second dummy electrode 58, and a dummy via hole 57. The first dummy electrode 56, the second dummy electrode 58, and the dummy via hole 57 may be provided in the wiring layer 30. The first dummy electrode 56 may be provided on the upper surface 16. For the second dummy electrode 58, an upper surface of the second dummy electrode 58 may be exposed to an upper surface of the wiring layer 30. The dummy via hole 57 may be arranged at a position overlapping the first dummy electrode 56 and the second dummy electrode 58 in the top view.

In the present example, the region information 66 and the capacitor information 68 are indicated by a presence or an absence of the dummy via hole 57 at each position. For example, by the presence or the absence of the dummy via hole 57 at one position, one bit of information is indicated. The presence or the absence of the dummy via hole 57 may be identified from an image, or may be identified from an electrical characteristic that can be measured by causing a probe or the like to contact each position. In FIG. 5, the dummy via hole 57 is provided at a position of a black circle, and the dummy via hole 57 is not provided at a position of a white circle. The dummy via holes 57 may be provided below all of the first dummy electrodes 56 in the information portion 64. In the case where the dummy via holes 57 are provided below all of the first dummy electrodes 56, the region information 66 and the capacitor information 68 may be indicated by the presence or the absence of dummy connection wiring provided at the dummy via hole 57.

FIG. 7 is a diagram showing another example of the electronic device 100 according to one embodiment of the present invention. The electronic device 100 in the present example includes a wiring layer 80 instead of the second bump 42, which is a difference from the electronic device 100 in FIG. 1. The wiring layer 80 may be provided in the Z axis direction between the connection substrate 10 and the circuit board 40. The wiring layer 80 may be formed of a photosensitive material 88. In the present example, the connection substrate 10 may be the first semiconductor wafer 60 (refer to FIG. 2), and may not be the first semiconductor wafer 60.

The connection substrate 10 may be provided with the plurality of through via structure portions 17. The plurality of through via structure portions 17 may have at least one connection through via 11 and at least one non-connection through via 19. The connection through via 11 may be electrically connected to the circuit board 40. The non-connection through via 19 may not be electrically connected to the circuit board 40.

The connection through via 11 is the through via structure portion 17 which functions as a through via as designed. The non-connection through via 19 is the through via structure portion 17 for which it is difficult to function as a through via, even though it is designed as a through via. In FIG. 7, a connection through via 11-1 refers to the through via structure portion 17-1 which functions as a through via. That is, the connection through via 11-1 is the same structure portion as the through via structure portion 17-1. Similarly, a connection through via 11-2 is the same structure portion as the through via structure portion 17-3, and a connection through via 11-3 is the same structure portion as the through via structure portion 17-4. In FIG. 7, a non-connection through via 19-1 refers to the through via structure portion 17-2 which functions as a non-connection through via. That is, the non-connection through via 19-1 is the same structure portion as the through via structure portion 17-2.

When the plurality of through via structure portions 17 are formed at the connection substrate 10, the yield of the plurality of through via structure portions 17 may be less than 100%, similar to the capacitor structure portion 12. The yield of the plurality of through via structure portions 17 refers to a ratio of the number of the connection through vias 11 to the total number of the plurality of through via structure portions 17.

The non-connection through via 19 may be a through via in the open state. The through via in the open state refers to a through via in which the electrical resistance value of the through via structure portion 17 exceeds a predetermined resistance threshold value between the upper surface 16 and the lower surface 18, due to a problem such as filling of a through opening with metal for setting a through via. The non-connection through via 19 is a defective through via. It is preferable that the non-connection through via 19 is not used for connection between the circuit board 40 and the electronic element 20. The connection through via 11 is a through via in which the electrical resistance value of the through via structure portion 17 is lower than or equal to a predetermined resistance threshold value between the upper surface 16 and the lower surface 18. The connection through via 11 is a good through via.

The connection substrate 10 may have at least one third connection electrode 84 and at least one fourth connection electrode 86. The third connection electrode 84, the fourth connection electrode 86, and connection wiring 82 may be provided inside the wiring layer 80. The third connection electrode 84 and the fourth connection electrode 86 may be provided in the lower surface 18 of the connection substrate 10.

The third connection electrode 84 is connected to the connection through via 11. The third connection electrode 84 may be provided to cover a lower part of the connection through via 11. One third connection electrode 84 may be provided to cover the lower part of one connection through via 11. The fourth connection electrode 86 is connected to the non-connection through via 19. The fourth connection electrode 86 may be provided to cover a lower part of the non-connection through via 19. One fourth connection electrode 86 may be provided to cover the lower part of one non-connection through via 19. The third connection electrode 84 is connected to the connection wiring 82. The fourth connection electrode 86 is not connected to the connection wiring 82.

The connection substrate 10 may further include at least one lower electrode 87. The lower electrode 87 may be provided inside the wiring layer 80. A lower surface of the lower electrode 87 may be exposed to a lower surface of the wiring layer 80. In the Z axis direction, one lower electrode 87 may be provided below one third connection electrode 84 or one fourth connection electrode 86. The connection wiring 82 may be arranged at a position overlapping the third connection electrode 84 and the lower electrode 87 in the top view.

The third connection electrode 84 is electrically connected to the circuit board 40. In the present example, the third connection electrode 84 is connected to the lower electrode 87 by the connection wiring 82. In this manner, the third connection electrode 84 is electrically connected to the circuit board 40. In the present example, the fourth connection electrode 86 is not connected to the lower electrode 87 by the connection wiring 82. In this manner, the fourth connection electrode 86 is not electrically connected to the circuit board 40. In the present example, the power supplied from the circuit board 40 is supplied to the electronic element 20, via the lower electrode 87, the connection wiring 82, the third connection electrode 84, the connection through via 11, the first connection electrode 34, the connection wiring 32, the upper electrode 37, and the first bump 24.

The connection through via 11 may be electrically connected to the first connection electrode 34. That is, the connection through via 11 may be electrically connected to the connection capacitor portion 13 (refer to FIG. 1). This makes it possible to supply the power supply voltage from the circuit board 40 to the electronic element 20 while the quality of the power supply voltage is ensured. The non-connection through via 19 may not be electrically connected to, or may be connected to the first connection electrode 34.

In the electronic device 100 in the present example, the connection wiring 82 is arranged based on a state of the through via structure portion 17. The state of the through via structure portion 17 may refer to either goodness or defectiveness of the through via structure portion 17, or the electrical resistance value. In the present example, the connection wiring 82 is connected to the good through via structure portion 17, but is not connected to the defective through via structure portion 17. That is, the connection wiring 82 is connected to the good through via structure portion 17 while avoiding the defective through via structure portion 17. Therefore, the electronic device design system 200 (described below) electrically connects the circuit board 40 to the electronic element 20 easily and efficiently.

FIG. 8 is a block diagram showing an example of the electronic device design system 200 according to one embodiment of the present invention. An electronic device manufacturing apparatus 300 is an apparatus for manufacturing the electronic device 100 (refer to FIG. 1 to FIG. 7). The electronic device design system 200 controls the electronic device manufacturing apparatus 300, thereby manufacturing the electronic device 100.

The electronic device design system 200 in the present example includes a measurement unit 210, a data generation unit 220, a control unit 230, a storage unit 240, and a signal application unit 250. The measurement unit 210, the data generation unit 220, the storage unit 240, and the signal application unit 250 will be described in a method of manufacturing the electronic device described below.

The electronic device design system 200 may be partially or entirely realized by a computer. The control unit 230 may be a CPU (Central Processing Unit) of the computer. When the electronic device design system 200 is realized by a computer, the computer may have a program installed to cause the computer to function as the electronic device design system 200.

FIG. 9 to FIG. 13 are diagrams showing other examples of the method of manufacturing the electronic device according to one embodiment of the present invention. The method of manufacturing the electronic device includes an electrical element formation step S100, an evaluation step S104, and a wiring formation step S120. The method of manufacturing the electronic device may include an electrode formation step S102, a classification step S106, a photosensitive material formation step S108, a via pattern formation step S110, an information portion formation step S112, a dummy electrode formation step S122, a through via exposure step S130, a connection substrate mounting step S140, and a second semiconductor wafer mounting step S200. The method of manufacturing the electronic device will be described by using, as the examples, the electronic device 100 shown in FIG. 1 to FIG. 7 and the electronic device design system 200 shown in FIG. 8.

The electrical element formation step S100 is a step of forming a plurality of electrical elements 120 in the connection substrate 10 formed of a semiconductor. In the example of FIG. 9, the electrical element 120 refers to the capacitor structure portion 12 and the through via structure portion 17. As described above, the electrical element 120 may be a passive element other than the capacitor structure portion 12. The connection substrate 10 may be the first semiconductor wafer 60 (refer to FIG. 2).

The electrical element formation step S100 may be a step of forming the plurality of electrical elements 120 having the same structure in the connection substrate 10. In a case of forming a plurality of types of electrical elements 120 in the connection substrate 10, the electrical element formation step S100 may be a step of forming the plurality of electrical elements 120 having the same structure for the electrical element 120 of a single type. In the present example, the electrical element formation step S100 is a step of forming the capacitor structure portions 12 having the same structure and the through via structure portions 17 having the same structure.

The electrical element formation step S100 may be a step of forming the electrical elements 120, the number of which is greater than the number of the electrical elements 120 to be connected to the connection wiring 32 (refer to FIG. 1, FIG. 2, and FIG. 7). As described above, the yield of the electrical element 120 may be less than 100%. Accordingly, in the electrical element formation step S100, it is preferable to form the electrical elements 120, the number of which is greater than the number of the electrical elements 120 to be connected to the connection wiring 32.

The electrode formation step S102 is a step of forming cover electrodes 340 above the plurality of capacitor structure portions 12, respectively. The electrode formation step S102 may be a step of further forming the first dummy electrode 56 (refer to FIG. 6) at a predetermined position in one region 62 (refer to FIG. 4) of the first semiconductor wafer 60. The electrode formation step S102 may be a step of further forming the first dummy electrode 56 in each of the plurality of regions 62 of the first semiconductor wafer 60.

The evaluation step S104 is a step of evaluating the electrical characteristic of each of the plurality of electrical elements 120. When the connection substrate 10 is the first semiconductor wafer 60, the evaluation step S104 is a step of evaluating the capacitor characteristic of each of the plurality of capacitor structure portions 12 formed at the first semiconductor wafer 60 in the electrical element formation step S100. When the connection substrate 10 is the first semiconductor wafer 60, the evaluation step S104 may be a step of evaluating each capacitor characteristic in a state in which the capacitor structure portion 12 is formed at the first semiconductor wafer 60. The first semiconductor wafer 60 may be a substrate which is cut out from an ingot and is not yet singulated. The first semiconductor wafer 60 may be a substrate of a disc shape in which an orientation flat or notch that indicates a crystal orientation of the semiconductor, is formed.

The evaluation step S104 may be a step of evaluating the capacitor characteristic of each of the plurality of capacitor structure portions 12, via a cover electrode 340. In the example of FIG. 9, the evaluation step S104 is a step in which the measurement unit 210 (refer to FIG. 8) uses a wafer probe 400 to evaluate the capacitor characteristic of each of the plurality of capacitor structure portion 12.

In the evaluation step S104, by measuring the capacitance value of each capacitor structure portion 12, the measurement unit 210 (refer to FIG. 8) may determine whether each capacitor structure portion 12 is either the connection capacitor portion 13 or the non-connection capacitor portion 14. In the evaluation step S104, the measurement unit 210 may measure a position of the determined capacitor structure portion 12 in the wafer surface of the first semiconductor wafer 60. The measurement unit 210 may have an encoder circuit to identify the position of the capacitor structure portion 12 in the wafer surface of the first semiconductor wafer 60.

The evaluation step S104 may include a step of maintaining each of the plurality of capacitor structure portions 12 at a predetermined temperature, or applying a predetermined voltage to each of the plurality of capacitor structure portions 12. In the evaluation step S104, the signal application unit 250 (refer to FIG. 8) may activate, via the wafer probe 400, a defect in the capacitor structure portion 12 by maintaining each of the plurality of capacitor structure portions 12 at a predetermined certain temperature for a certain period of time. The activation of the defect in the capacitor structure portion 12 refers to activating the defectiveness that may potentially exist in the capacitor structure portion 12. The predetermined certain temperature may be 100° C. or higher, may be 120° C. or higher, or may be 130° C. or higher. The predetermined certain period of time may be 10 minutes or longer, may be 20 minutes or longer, may be 40 minutes or longer, or may be one hour or longer.

In the evaluation step S104, the signal application unit 250 (refer to FIG. 8) may activate, via the wafer probe 400, a defect in the capacitor structure portion 12 by alternately repeating of maintaining each of the plurality of capacitor structure portions 12 at a predetermined first temperature for a first period of time, and maintaining at a predetermined second temperature for a second period of time. Here, the second temperature is higher than the first temperature. The predetermined first temperature may be 0° C. or lower, may be −20° C. or lower, or may be −40° C. or lower. The predetermined second temperature may be 100° C. or higher, may be 120° C. or higher, or may be 130° C. or higher. The predetermined first period of time and second period of time may be 10 minutes or longer, may be 20 minutes or longer, may be 40 minutes or longer, or may be one hour or longer.

The signal application unit 250 may activate, via the wafer probe 400, a defect in the capacitor structure portion 12 by applying a voltage to each of the plurality of capacitor structure portions 12. The voltage may be a constant voltage determined by a breakdown voltage of the capacitor structure portion 12. When the signal application unit 250 (refer to FIG. 8) is able to apply a variable voltage, the voltage determined by the breakdown voltage of the capacitor structure portion 12 is a maximum voltage when the signal application unit 250 is operated. The activation of the defect in the capacitor structure portion 12 refers to so-called burn-in of the capacitor structure portion 12.

The evaluation step S104 may include a step of evaluating the electrical characteristic of each of the plurality of through via structure portions 17. When the connection substrate 10 is the first semiconductor wafer 60, the evaluation step S104 is a step of evaluating the electrical characteristic of each of the plurality of through via structure portions 17 formed at the first semiconductor wafer 60 in the electrical element formation step S100. The evaluation step S104 may be a step of evaluating the electrical characteristic of each through via structure portion 17 in a state in which the through via structure portion 17 is formed at the first semiconductor wafer 60.

In the evaluation step S104, by measuring the electrical resistance value of each through via structure portion 17, the measurement unit 210 (refer to FIG. 8) may determine whether each through via structure portion 17 is either the connection through via 11 or the non-connection through via 19. In the evaluation step S104, the measurement unit 210 may measure a position of the measured through via structure portion 17 in the wafer surface of the first semiconductor wafer 60.

The classification step S106 is a step of classifying the plurality of capacitor structure portions 12 into the connection capacitor portion 13 and the non-connection capacitor portion 14, based on an evaluation result of the capacitor characteristic in the evaluation step S104. The classification step S106 may be a step in which by measuring the capacitance value of each capacitor structure portion 12, the measurement unit 210 (refer to FIG. 8) classifies the plurality of capacitor structure portions 12 into the connection capacitor portion 13 and the non-connection capacitor portion 14.

The classification step S106 may include a storage step in which the storage unit 240 (refer to FIG. 8) stores a classification result. The storage step may be a step in which the storage unit 240 stores the position of the capacitor structure portion 12 in the wafer surface of the first semiconductor wafer 60, and the classification result of the capacitor structure portion 12, in association with each other. In the storage step, the storage unit 240 may store the capacitance value of each capacitor structure portion 12 measured in the evaluation step S104. In the storage step, the storage unit 240 may store the position of the through via structure portion 17 in the wafer surface of the first semiconductor wafer 60, and the electrical resistance value of each through via structure portion 17 measured in evaluation step S104, in association with each other.

The classification step S106 may be a step of further classifying the cover electrodes 340 (refer to the step S102) into at least one first connection electrode 34 and at least one second connection electrode 36, based on the evaluation result of the capacitor characteristic in the evaluation step S104. The first connection electrode 34 covers the upper part of the connection capacitor portion 13, and is connected to the connection capacitor portion 13. The second connection electrode 36 covers the upper part of the non-connection capacitor portion 14, and is connected to the non-connection capacitor portion 14.

The photosensitive material formation step S108 is a step of forming the photosensitive material 38 on the connection substrate 10. The photosensitive material formation step S108 may be a step of forming the photosensitive materials 38 on the upper surface 16 of the connection substrate 10, on the first connection electrode 34, and on the second connection electrode 36.

The via pattern formation step S110 is a step of forming a via pattern 350 above the connection capacitor portion 13, and not forming the via pattern 350 above the non-connection capacitor portion 14, in the photosensitive material 38. The via pattern formation step S110 may include a data generation step in which the data generation unit 220 (refer to FIG. 8) generates data related to coordinates for forming the via pattern, based on the position of the capacitor structure portion 12 in the wafer surface of the first semiconductor wafer 60, and the classification result of the capacitor structure portion 12, which are stored in the storage unit 240 in association with each other (refer to FIG. 8). The via pattern formation step S100 may be a step in which a maskless aligner 360 forms the via pattern 350 above the connection capacitor portion 13, based on the data generated in the data generation step, and does not form the via pattern 350 above the non-connection capacitor portion 14.

The information portion formation step S112 is a step of forming the information portion 64 including the region information 66 and the capacitor information 68 in the first semiconductor wafer 60. In the present example, the information portion formation step S112 is a step of forming the dummy via hole 57 in the first semiconductor wafer 60, as the information portion 64. The information portion formation step S112 may be a step in which the data generation unit 220 (refer to FIG. 8) generates position data for the dummy via hole 57 to form the dummy via hole 57 at the position of the position data, based on the position of the capacitor structure portion 12 in the wafer surface of the first semiconductor wafer 60, and the classification result of the capacitor structure portion 12, which are stored in the storage unit 240 (refer to FIG. 8).

The via pattern formation step S110 and the information portion formation step S112 may be performed at the same timing. The via pattern formation step S110 and the information portion formation step S112 may be performed at different timings.

The wiring formation step S120 is a step of forming the connection wiring 32 which is connected to at least one of the plurality of electrical elements 120, based on the evaluation result of the electrical characteristic of the electrical element 120 in the evaluation step S104. The wiring formation step S120 may be a step of forming the connection wiring 32, based on the classification result in the classification step S106 (refer to FIG. 10). The wiring formation step S120 may be a step of forming the connection wiring 32 in the via pattern 350 (refer to the step S110). In the example of FIG. 11, the wiring formation step S120 is a step of forming the connection wiring 32 which is connected to the connection capacitor portion 13, based on the evaluation result of the capacitor characteristic of the capacitor structure portion 12.

The wiring formation step S120 may be a step in which the connection wiring 32 is not formed at at least another one of the plurality of electrical elements 120, based on the evaluation result of the electrical characteristic of the electrical element 120 in the evaluation step S104. In the example of FIG. 11, the wiring formation step S120 is a step in which the connection wiring 32 that is connected to the non-connection capacitor portion 14, is not formed, based on the evaluation result of the capacitor characteristic of the capacitor structure portion 12.

The wiring formation step S120 may be a step of forming the connection wiring 32 in a state in which the capacitor structure portion 12 is formed at the first semiconductor wafer 60, based on the classification result of the classification step S106 (refer to FIG. 10). The expression of forming the connection wiring 32 in a state in which the capacitor structure portion 12 is formed at the first semiconductor wafer 60 refers to forming the connection wiring 32 in the first semiconductor wafer 60 which is cut out from an ingot and is not yet singulated.

In the classification step S106, the plurality of capacitor structure portions 12 are classified into the connection capacitor portion 13 and the non-connection capacitor portion 14. In the storage unit 240 (refer to FIG. 8), the position of the capacitor structure portion 12 in the wafer surface of the first semiconductor wafer 60, and the classification result of the capacitor structure portion 12, are stored in association with each other. In the data generation step, the data generation unit 220 (refer to FIG. 8) generates the data related to coordinates for forming the via pattern, based on the position of the capacitor structure portion 12 in the wafer surface of the first semiconductor wafer 60, and the classification result of the capacitor structure portion 12, which are stored in the storage unit 240 in association with each other. In the via pattern formation step S100, the maskless aligner 360 forms the via pattern 350 above the connection capacitor portion 13, based on the data generated in the data generation step, and does not form the via pattern 350 above the non-connection capacitor portion 14. By these steps, in the wiring formation step S120, even when the connection wiring 32 is formed in a state in which the capacitor structure portion 12 is formed at the first semiconductor wafer 60, the yield of the plurality of electronic elements 20 (refer to FIG. 1, FIG. 2, and FIG. 7) is less likely to be reduced. The yield of the plurality of electronic elements 20 refers to an occupying ratio of the number of the electronic elements 20 which is normally operated, to the total number of the plurality of electronic elements 20 formed above the first semiconductor wafer 60.

The wiring formation step S120 may include a step of forming one upper electrode 37 above one first connection electrode 34 or one second connection electrode 36 in the Z axis direction. The step may be performed after the step of forming the connection wiring 32.

The dummy electrode formation step S122 is a step of forming at least one second dummy electrode 58 above the first dummy electrode 56. The dummy electrode formation step S122 may be performed at the same timing as, or may be performed at a different timing from that of the step of forming the upper electrode 37 in the wiring formation step S120.

The through via exposure step S130 is a step of exposing the through via structure portion 17 to the lower surface 18. The through via exposure step S130 may be a step of exposing the through via structure portion 17 by cutting the lower surface of the connection substrate 10. The through via exposure step S130 may be a step of exposing the through via structure portion 17 by grinding the lower surface of the first semiconductor wafer 60.

The connection substrate mounting step S140 is a step of mounting the connection substrate 10 on the circuit board 40. The connection substrate mounting step S140 may be a step of mounting the connection substrate 10 on the circuit board 40, while aligning the position of the through via structure portion 17 in the XY plane with the position of the second bump 42 in the XY plane.

The second semiconductor wafer mounting step S200 is a step of mounting the second semiconductor wafer 70 provided with the electronic element 20, above the first semiconductor wafer 60. The second semiconductor wafer mounting step S200 may include a step of forming the first bump 24 to be in contact with the upper surface of the upper electrode 37. The second semiconductor wafer mounting step S200 may be a step of mounting the second semiconductor wafer 70 above the first semiconductor wafer 60, while aligning the first semiconductor wafer 60 and the second semiconductor wafer 70 in the XY plane. By performing the second semiconductor wafer mounting step S200, the electronic device 100 (refer to FIG. 2) is completed.

FIG. 14 is a diagram showing another example of the method of manufacturing the electronic device according to one embodiment of the present invention. The method of manufacturing the electronic device in the present example includes a specification step S107 instead of a classification step S106, which is a difference from the method of manufacturing the electronic device shown in FIG. 9 to FIG. 13. In the present example, the electronic element formation step S100 to the evaluation step S104, and the photosensitive material formation step S108 to the second semiconductor wafer mounting step S200 are the same as those of the method of manufacturing the electronic device shown in FIG. 9 to FIG. 13.

The specification step S107 is a step of specifying a group 122 of the capacitor structure portions 12 which have capacitance values higher than or equal to a predetermined capacitance value, based on the evaluation result of the capacitor characteristic in the evaluation step S104. The group 122 of the capacitor structure portions 12 includes at least one capacitor structure portion 12. FIG. 14 shows two groups 122 (a group 122-1 and a group 122-2). The group 122-1 includes the capacitor structure portion 12-1 to the capacitor structure portion 12-16. The group 122-2 includes the capacitor structure portion 12-21 to the capacitor structure portion 12-24.

The specification step S107 is a step of grouping the capacitor structure portions 12 such that the total capacitance value of all of the capacitor structure portions 12 in one group 122 is higher than or equal to a predetermined capacitance value. Therefore, one group 122 may include a non-connection capacitor portion 14. In the example of FIG. 14, the group 122-1 includes two non-connection capacitor portions 14.

The specification step S107 may be a step in which the capacitor structure portions 12 are not grouped, when the total capacitance value of all of the capacitor structure portions 12 in one group 122 is not higher than or equal to a predetermined capacitance value. Therefore, even the connection capacitor portion 13 may exist as the capacitor structure portion 12 which is not included in any group 122. In the example of FIG. 14, the connection capacitor portion 13-15 to the connection capacitor portion 13-18 are the capacitor structure portions 12 which are not included in any group 122.

The specification step S107 may be a step of further classifying the cover electrodes 340 (refer to the step S102) into at least one first connection electrode 34 and at least one second connection electrode 36, based on the evaluation result of the capacitor characteristic in the evaluation step S104. The first connection electrode 34 covers an upper part of at least one capacitor structure portion 12 in each group 122, and is connected to the connection capacitor portion 13 or the non-connection capacitor portion 14. The second connection electrode 36 covers the upper part of the capacitor structure portion 12 which is not included in any group 122, and is connected to the connection capacitor portion 13 or the non-connection capacitor portion 14.

In the present example, the wiring formation step S110 (refer to FIG. 10) is a step of forming the connection wiring 32, based on a specification result of group 122 in the specification step S107. The connection wiring 32 may be formed above the first connection electrode 34 in FIG. 14.

One group 122 may be one closed region in the top view of the connection substrate 10. One group 122 may be constituted by two or more closed regions in the top view of the connection substrate 10. The two or more closed regions may be spaced apart from each other in the top view of the connection substrate 10. In the present example, the connection wiring 32 is formed based on the specification result of group 122 in the specification step S107. Therefore, even when one group 122 is constituted by two or more regions that are spaced apart from each other, the overall capacitance value of all of the capacitor structure portions 12 in one group 122 can be higher than or equal to a predetermined capacitance value, by the connection wiring 32 being formed.

FIG. 15 is a block diagram showing another example of the electronic device design system 200 according to one embodiment of the present invention. The electronic device design system 200 in the present example includes an optical characteristic measurement unit 280 instead of the measurement unit 210, which is a difference from the electronic device design system 200 in FIG. 8. The optical characteristic measurement unit 280 may have a light source 282 and a light receiving unit 284.

FIG. 16 and FIG. 17 are diagrams showing other examples of the method of manufacturing the electronic device according to one embodiment of the present invention. The method of manufacturing the electronic device in the present example further includes a liquid crystal layer formation step S1090 and a liquid crystal layer removal step S1094, and includes an evaluation step S1092 instead of the evaluation step S104, which is a difference from the method of manufacturing the electronic device in FIG. 9 to FIG. 13. In the present example, the electronic element formation step S100, the electrode formation step S102, the classification step S106 and the photosensitive material formation step S108, and the via pattern formation step S110 to the second semiconductor wafer mounting step S200, are the same as those of the method of manufacturing the electronic device in FIGS. 9 to 13.

The liquid crystal layer formation step S1090 is a step of forming a liquid crystal layer 290 above the connection substrate 10. In the present example, the liquid crystal layer formation step S1090 is a step of forming the liquid crystal layer 290 on an upper surface of the photosensitive material 38 in the wiring layer 30.

The evaluation step S1092 is a step of evaluating the electrical characteristic of each of the plurality of electrical elements 120 (in the present example, the capacitor structure portion 12), by applying the voltage between an upper surface of the liquid crystal layer 290 and the connection substrate 10. The optical characteristic measurement unit 280 may further include a first lens 285, a second lens 287, a spectroscopic unit 288, and a voltage application unit 286. The voltage between the upper surface of the liquid crystal layer 290 and the connection substrate 10 may be applied by the voltage application unit 286. The liquid crystal layer removal step S1094 is a step of removing the liquid crystal layer 290 formed in the liquid crystal layer formation step S1090.

FIG. 18 is a schematic diagram of a part of an upper surface of the liquid crystal layer 290, in a state in which a voltage is applied between the upper surface of the liquid crystal layer 290 and the connection substrate 10. In the present example, one circle in FIG. 18 corresponds to four capacitor structure portions 12 (for example, the capacitor structure portion 12-1 to the capacitor structure portion 12-4 in FIG. 16). In the evaluation step S1092, when the voltage is applied between the upper surface of the liquid crystal layer 290 and the connection substrate 10, a state of distortion occurring in the liquid crystal layer 290 is changed, depending on the number and positions of the connection capacitor portions 13 and the non-connection capacitor portions 14. The change in this state can appear, as an optical contrast, on the upper surface of the liquid crystal layer 290. In the evaluation step S1092, the optical characteristic measurement unit 280 (refer to FIG. 15) evaluates the capacitor characteristic of the capacitor structure portion 12 by detecting this optical contrast of the liquid crystal layer 290.

While the present invention has been described by way of the embodiments, the technical scope of the present invention is not limited to the above-described embodiments. It is apparent to persons skilled in the art that various alterations or improvements can be made to the above described embodiments. It is also apparent from description of the claims that the embodiments to which such changes or improvements are made may be included in the technical scope of the present invention.

It should be noted that each process of the operations, procedures, steps, stages, and the like performed by the apparatus, system, program, and method shown in the claims, specification, or drawings can be executed in any order as long as the order is not indicated by “prior to”, “before”, or the like and as long as the output from a previous process is not used in a later process. Even if the operation flow is described using phrases such as “first” or “next” for the sake of convenience in the claims, specification, or drawings, it does not necessarily mean that the process must be performed in this order.

What is claimed is:

1. An electronic device comprising:
a connection substrate which is provided with a plurality of capacitor structure portions;
an electronic element which is provided above the connection substrate; and
connection wiring which connects the electronic element to the connection substrate, wherein
the plurality of capacitor structure portions have at least one connection capacitor portion which is connected to the connection wiring, and at least one non-connection capacitor portion which is not connected to the connection wiring.

2. The electronic device according to claim 1, wherein
the at least one non-connection capacitor portion is a capacitor in a shorted state or an open state.

3. The electronic device according to claim 1, wherein
the connection substrate is a first semiconductor wafer.

4. The electronic device according to claim 3, wherein
each of the plurality of capacitor structure portions is a trench structure provided from an upper surface of the first semiconductor wafer to an inside.

5. The electronic device according to claim 4, wherein
the at least one connection capacitor portion includes a first capacitor electrode provided on an inner wall of the trench structure, and
the first capacitor electrode is in contact with the first semiconductor wafer.

6. The electronic device according to claim 3, wherein
the first semiconductor wafer is provided with an information portion which includes region information indicating a region in the first semiconductor wafer, and capacitor information indicating a capacitor characteristic of at least one capacitor structure portion in the region among the plurality of capacitor structure portions.

7. The electronic device according to claim 3, further comprising:
a second semiconductor wafer, wherein
the electronic element is provided at the second semiconductor wafer.

8. The electronic device according to claim 1, wherein
the connection substrate has at least one first connection electrode which is provided to cover an upper part of the connection capacitor portion and which is connected to the at least one connection capacitor portion, and at least one second connection electrode which is provided to cover an upper part of the at least one non-connection capacitor portion and which is connected to the at least one non-connection capacitor portion,
the at least one first connection electrode is connected to the connection wiring, and
the at least one second connection electrode is not connected to the connection wiring.

9. The electronic device according to claim 8, further comprising:
a circuit board which is provided below the connection substrate, wherein
the connection substrate is further provided with a plurality of through via structure portions, and
the plurality of through via structure portions have at least one connection through via which is electrically connected to the circuit board, and at least one non-connection through via which is not electrically connected to the circuit board.

10. The electronic device according to claim 9, wherein
the non-connection through via is a through via in which an electrical resistance value exceeds a resistance threshold value, and the connection through via is a through via in which an electrical resistance value is lower than or equal to the resistance threshold value.

11. The electronic device according to claim 9, wherein
the connection substrate further has at least one third connection electrode which is provided to cover a lower part of the connection through via, and which is connected to the connection through via, and
the at least one third connection electrode is electrically connected to the circuit board.

12. The electronic device according to claim 9, wherein
the at least one connection through via is electrically connected to the at least one first connection electrode.

13. A method of manufacturing an electronic device, comprising:
performing an electrical element formation by forming a plurality of electrical elements in a connection substrate formed of a semiconductor;
performing an evaluation by evaluating an electrical characteristic of each of the plurality of electrical elements; and
performing a wiring formation by forming connection wiring which is connected to at least one of the plurality of electrical elements, based on an evaluation result of the electrical characteristic.

14. The method of manufacturing an electronic device according to claim 13, wherein
the performing the electrical element formation is forming the plurality of electrical elements having a same structure, and is forming the plurality of electrical elements, a number of which is greater than a number of at least one electrical element to be connected to the connection wiring, and
in the performing the wiring formation, the connection wiring is not formed at at least another one of the plurality of electrical elements, based on the evaluation result of the electrical characteristic.

15. The method of manufacturing an electronic device according to claim 13, wherein
the connection substrate is a first semiconductor wafer,
the plurality of electrical elements are respectively capacitor structure portions,
the performing the evaluation is evaluating a capacitor characteristic of each of a plurality of capacitor structure portions of the capacitor structure portions formed at the first semiconductor wafer in the performing the electrical element formation,
the method of manufacturing an electronic device further comprises performing a classification by classifying the plurality of capacitor structure portions into a connection capacitor portion which is connected to the connection wiring, and a non-connection capacitor portion which is not connected to the connection wiring, based on the evaluation result of the capacitor characteristic, and
the performing the wiring formation is forming the connection wiring based on a classification result in the performing the classification.

16. The method of manufacturing an electronic device according to claim 15, wherein
the performing the evaluation is evaluating each capacitor characteristic which is the capacitor characteristic in a state in which the plurality of capacitor structure portions are formed at the first semiconductor wafer.

17. The method of manufacturing an electronic device according to claim 15, wherein
the performing the wiring formation is forming the connection wiring in a state in which the plurality of capacitor structure portions are formed at the first semiconductor wafer, based on the classification result in the performing the classification.

18. The method of manufacturing an electronic device according to claim 15, further comprising:
performing an electrode formation by forming a cover electrode above each of the capacitor structure portions, wherein
the performing the evaluation is evaluating the capacitor characteristic of each of the plurality of capacitor structure portions, via the cover electrode, and
the performing the classification is further classifying cover electrodes, each of which is the cover electrode, into at least one first connection electrode which covers an upper part of the connection capacitor portion and which is connected to the connection capacitor portion, and at least one second connection electrode which covers an upper part of the non-connection capacitor portion and which is connected to the non-connection capacitor portion, based on the evaluation result of the capacitor characteristic.

19. The method of manufacturing an electronic device according to claim 13, wherein
the connection substrate is a first semiconductor wafer,
each of the plurality of electrical elements is a capacitor structure portion,
the method of manufacturing an electronic device further comprises performing a specification by specifying a group including at least one of the capacitor structure portions which has a capacitance value higher than or equal to a predetermined capacitance value, based on the evaluation result of a capacitor characteristic in the capacitor structure portion, and
the performing the wiring formation is forming the connection wiring based on a specification result in the performing the specification.

20. The method of manufacturing an electronic device according to claim 15, further comprising:
performing an information portion formation by forming, at the first semiconductor wafer, an information portion which includes region information indicating a region in the first semiconductor wafer, and capacitor information indicating the capacitor characteristic of at least one of the capacitor structure portions in the region.

21. The method of manufacturing an electronic device according to claim 15, wherein
the performing the evaluation includes maintaining each of the plurality of capacitor structure portions at a predetermined temperature, or applying a predetermined voltage to each of the plurality of capacitor structure portions.

22. The method of manufacturing an electronic device according to claim 15, further comprising:
performing a photosensitive material formation by forming a photosensitive material on the connection substrate, after the performing the electrical element formation; and
performing a via pattern formation by forming a via pattern above the connection capacitor portion, and not forming a via pattern above the non-connection capacitor portion, in the photosensitive material, wherein
the performing the wiring formation is forming the connection wiring on the via pattern.

23. The method of manufacturing an electronic device according to claim 13, further comprising:
performing a liquid crystal layer formation by forming a liquid crystal layer above the connection substrate, after the performing the electrical element formation, wherein
the performing the evaluation is evaluating the electrical characteristic of each of the plurality of electrical elements, by applying a voltage between an upper surface of the liquid crystal layer and the connection substrate, and
the method of manufacturing an electronic device further comprises performing a liquid crystal layer removal by removing the liquid crystal layer, after the performing the evaluation and before the performing the wiring formation.

24. The method of manufacturing an electronic device according to claim 15, further comprising:
performing a second semiconductor wafer mounting by mounting a second semiconductor wafer provided with an electronic element, above the first semiconductor wafer, after the performing the wiring formation.
